(19) United States
(12) Patent Application Publication
(10) Pub. No.: US 2014/0347828 A1
(43) Pub. Date: Nov. 27, 2014

(54) ELECTRONIC APPARATUS

(71) Applicant: KABUSHIKI KAISHA TOSHIBA, Tokyo (JP)

(72) Inventors: Shinya Hayashiyama, Tachikawa-shi (JP); Makoto Tanaka, Ome-shi (JP)

(73) Assignee: KABUSHIKI KAISHA TOSHIBA, Tokyo (JP)

(21) Appl. No.: 14/059,839

(22) Filed: Oct. 22, 2013

(30) Foreign Application Priority Data
May 23, 2013 (JP) 2013-108729

(51) Int. Cl. H05K 1/02

(52) U.S. Cl. CPC H05K 1/0271
USPC 361/752; 361/748

(57) ABSTRACT

According to one embodiment, an electronic apparatus includes a substrate with a plurality of conductors, a component with a plurality of first terminals, and a deformation suppressing member attached to the substrate. The first terminals of the component are arranged in a first direction and connected to the conductors. When a certain bending deformation occurs in the substrate, the deformation suppressing member is configured to convert the certain bending deformation into a bending deformation in a direction perpendicular with the first direction.

### CROSS-REFERENCE TO RELATED APPLICATIONS

This application is based upon and claims the benefit of priority from Japanese Patent Application No. 2013-108729, filed May 23, 2013, the entire contents of which are incorporated herein by reference.

### FIELD

Embodiments described herein relate generally to an electronic apparatus.

### BACKGROUND

In various electronic apparatuses, a device with a plurality of terminals is mounted on a substrate. For instance, such a surface mount device as a ball grid array (BGA) is known as an example of the device.

When, for example, a physical shock is exerted on an electronic apparatus, the substrate incorporated therein may be deformed to be curved. If the substrate is deformed, stress may concentrate in a connection between the substrate and a terminal positioned at an end or a corner of the device, thereby damaging the connection.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary front view illustrating a TV set according to a first embodiment;

FIG. 2 is an exemplary plan view illustrating a module employed in the first embodiment;

FIG. 3 is an exemplary enlarged plan view illustrating part of the module of FIG. 2;

FIG. 4 is an exemplary cross-sectional view taken along line F4-F4 of FIG. 3;

FIG. 5 is an exemplary schematic perspective view illustrating a state in which a bending deformation has occurred in a printed wiring board in the first embodiment;

FIG. 6 is an exemplary plan view illustrating part of a module employed in a second embodiment;

FIG. 7 is an exemplary plan view illustrating part of a module employed in a third embodiment;

FIG. 8 is an exemplary plan view illustrating part of a module employed in a fourth embodiment; and

FIG. 9 is an exemplary plan view illustrating the internal structure of a TV set according to a fifth embodiment.

### DETAILED DESCRIPTION

Various embodiments will be described hereinafter with reference to the accompanying drawings. In general, according to one embodiment, an electronic apparatus includes a substrate with a plurality of conductors, a component with a plurality of first terminals, and a deformation suppressing member attached to the substrate. The first terminals of the component are arranged in a first direction and connected to the conductors. When a certain bending deformation occurs in the substrate, the deformation suppressing member is configured to convert the certain bending deformation into a bending deformation in a direction perpendicular with the first direction.

### First Embodiment

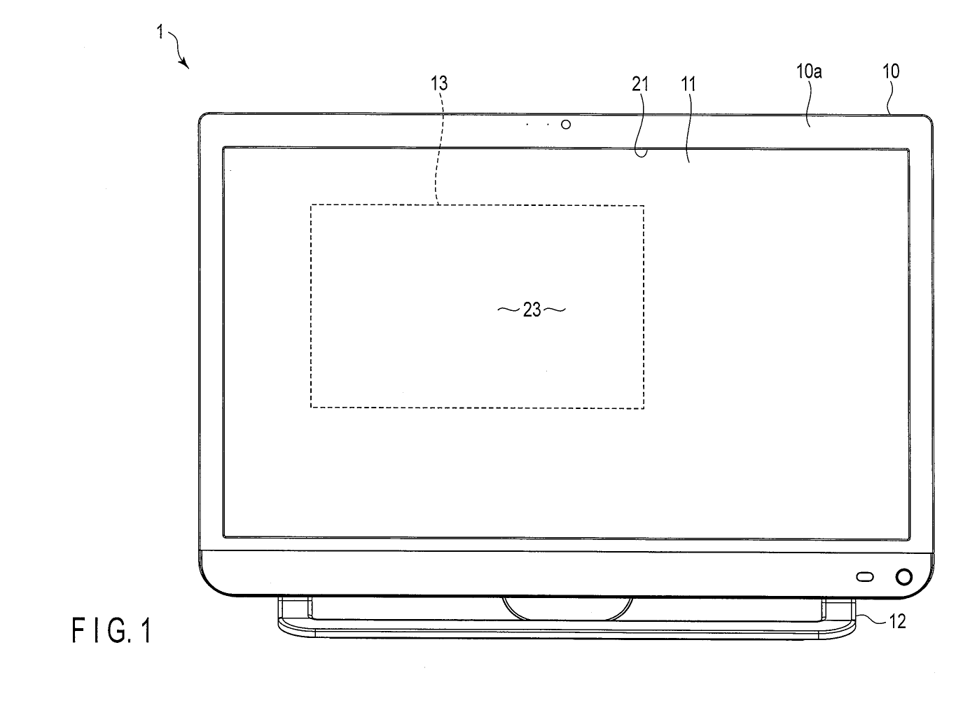

Referring FIGS. 1 to 5, a first embodiment will be described. In this specification, the side closer to a user is defined as the front side, the side remoter from the user is defined as the rear side, the side viewed left from the user is defined as the left side, the side viewed right from the user is defined as the right side, the side viewed upside from the user is defined as the upside, and the side viewed downside from the user is defined as the downside. Further, one or more expressions may be used to indicate a single element that can be expressed in various ways. However, this does not deny that an element indicated by only one expression can be expressed in a different way, or the use of other expressions currently not used is not limited. In addition, each figure schematically shows an embodiment, and therefore elements may differ in size, shape and/or arrangement between the figures.

FIG. 1 is an exemplary front view illustrating a television receiver 1 (hereinafter, a television). The television 1 is an example of an electronic apparatus. The electronic apparatus is not limited to a television, but may include other devices, such as a personal computer, a monitor, a tablet device, a cellular phone, a smartphone, a camera, and a copy machine with electronic components.

The television 1 shown in FIG. 1 is a flat-screen liquid crystal television, and comprises a housing 10, a display 11, a stand 12 and a module 13.

The housing 10 is formed flat and rectangular. A rectangular display opening 21 is formed in the front surface 10a of the housing 10. The display opening 21 is covered with, for example, a transparent glass plate.

The display 11 is, for example, a liquid crystal display, and has a display surface 23 for displaying images thereon. The images include still and moving images. The display 11 is contained in the housing 10. The display surface 23 is exposed to the outside through the display opening 21.

The stand 12 is attached to the housing 10, and is placed on, for example, a TV mount surface. The stand 12 supports the housing 10 so that the display surface 23 of the display 11 stands straight.

As indicated by the broken line in FIG. 1, the module 13 is contained in the housing 10 at a position near the backside of the display 11. The module 13 is connected to the display 11 and provided with various components for controlling the display 11.

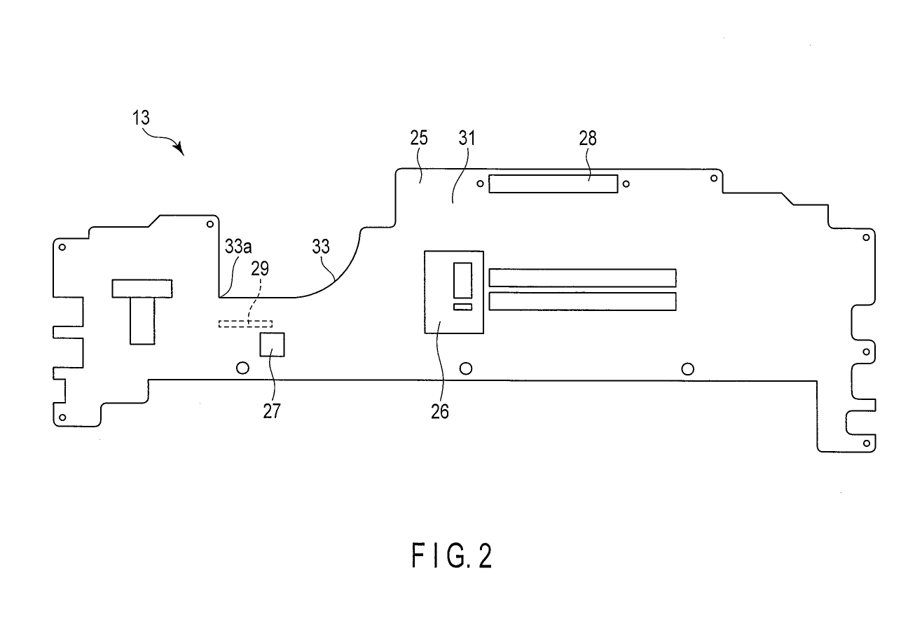

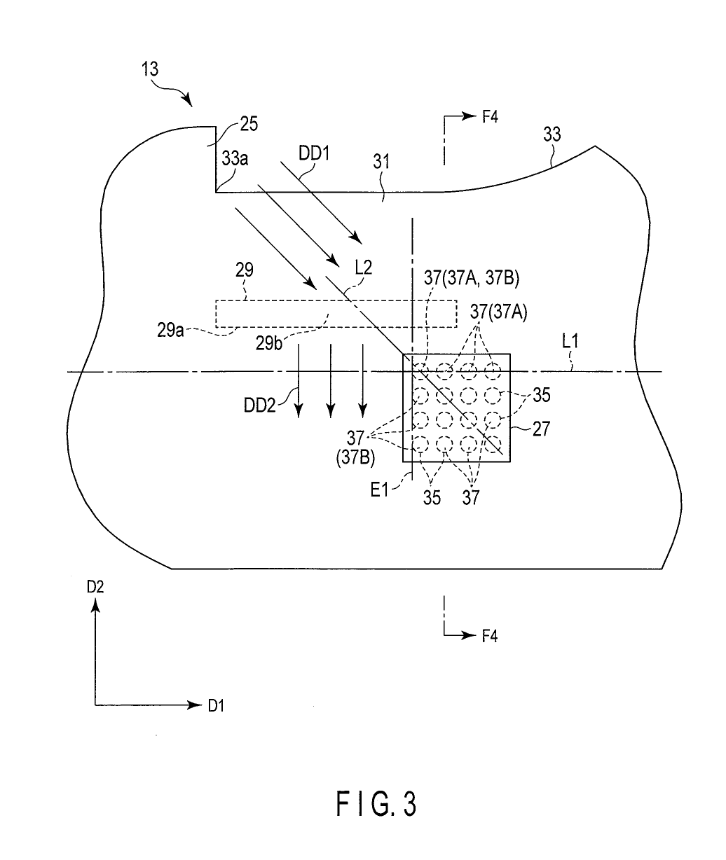

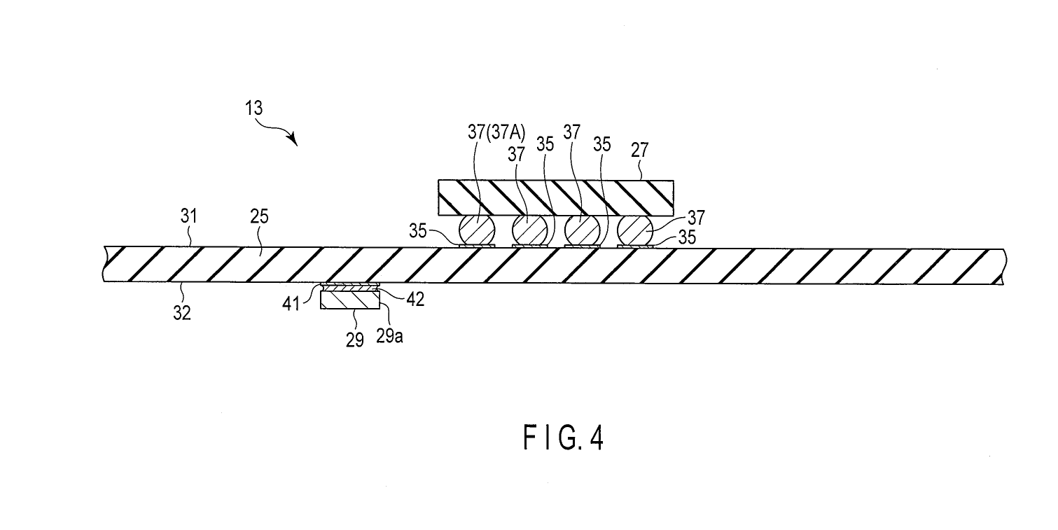

FIG. 2 is an exemplary plan view of the module 13. FIG. 3 is an exemplary enlarged plan view illustrating part of the module 13. FIG. 4 is an exemplary cross-sectional view of the module 13 taken along line F4-F4 of FIG. 3. As shown in FIG. 2, the module 13 comprises a printed wiring board 25, a CPU 26, a Ball Grid Array (BGA) 27, a connector 28 and a deformation suppressing member 29. The printed wiring board 25 is an example of a substrate. The BGA 27 is an example of a component.

The printed wiring board 25 is secured to a plurality of bosses provided on the inner surface of the housing 10, using, for example, a plurality of screws. As shown in FIG. 4, the printed wiring board 25 has opposite surfaces, i.e., a first surface 31 and a second surface 32. The first surface 31 faces the rear surface of the display 11. The second surface 32 is oriented backward of the television 1.

As shown in FIG. 2, a recess 33 is formed in the printed wiring board 25 and is used to receive, for example, a cooling fan. The recess 33 has a corner 33a formed by two intersecting linear edges of the printed wiring board 25 that define the recess 33.

The other electronic components, such as the CPU 26, the Ball Grid Array (BGA) 27, the connector 28 and a condenser, are mounted on the first surface 31 of the printed wiring board 25. Further, as shown in FIG. 4, other various electronic components including a tuner and the deformation suppressing member 29 are attached to the second surface 32 of the printed wiring board 25. A plurality of wiring patterns are formed on each of the first and second surfaces 31 and 32 of the printed wiring board 25.

A cable terminal is mounted on the second surface 32 of the printed wiring board 25. The cable terminal is electrically connected to the tuner, and projects from the rear surface of the housing 10 rearward of the television 1. By connecting an antenna cable to the cable terminal, the tuner can receive television signals.

As shown in FIG. 4, a plurality of pads 35 are provided on the first surface 31 of the printed wiring board 25. The pads 35 are examples of conducting members and are also referred to as lands or connections. The pads 35 are formed, for example, circular, and arranged in a matrix.

As shown in FIG. 3, the BGA 27 is formed square, and has a plurality of solder balls 37. The solder balls 37 are examples of first and second terminals. The solder balls 37 are arranged in a matrix in accordance with the matrix arrangement of the pads 35. In other words, the solder balls 37 are arranged in a first direction D1 and in a second direction D2 that perpendicular the first direction D1. The second direction D2 may incline at an angle other than 90° with respect to the first direction D1.

In FIG. 3, the uppermost solder balls 37 will be referred to as solder balls 37A for convenience. The solder balls 37A are examples of first terminals.

Similarly, in FIG. 3, the leftmost solder balls 37 will be referred to as solder balls 37B for convenience. The solder balls 37B are examples of second terminals.

In the first embodiment, the expression “solder balls 37” indicates all solder balls, i.e., both the solder balls 37A and 37B. The one of the solder balls 37 that is positioned at the upper left corner is regarded as a solder ball 37A and also as a solder ball 37B.

The pads 35 are arranged in accordance with the solder balls 37. In other words, the pads 35 are arranged at regular intervals in both the first and second directions D1 and D2. The solder balls 37 are electrically connected to the respective pads 35 by means of, for example, solder. By thus connecting the solder balls to the pads 35, the BGA 27 is fixed to the printed wiring board 25. An underfill resin may be filled in the clearance between the BGA 27 and the printed wiring board 25.

The deformation suppressing member 29 is, for example, a metal plate. This metal plate is formed of, for example, tinned stainless steel. The material of the deformation suppressing member 29 is not limited to a metal, but may be other materials, such as ceramic.

The deformation suppressing member 29 is higher rigid and thinner than the printed wiring board 25, and has a linear expansion coefficient closer to that of the printed wiring board 25. The rigidity, thickness and linear expansion coefficient of the deformation suppressing member 29 can be varied.

As shown in FIG. 3, the deformation suppressing member 29 is formed rectangular such that it extends in the first direction D1. However, the shape of the deformation suppressing member 29 is not limited to a rectangular one. It is sufficient if the deformation suppressing member 29 extends in the first direction D1 or has a portion extending in the first direction D1. For instance, the deformation suppressing member 29 may be formed as a wave-shaped plate member that extends in the first direction D1 as a whole.

As shown in FIG. 4, a dummy pattern member 41 is formed on the second surface 32 of the printed wiring board 25. The dummy pattern member 41 is formed of a metal film like the wiring patterns provided on the second surface 32. The dummy pattern member 41 is electrically isolated from the circuit that is formed by the wiring patterns. Further, the dummy pattern member 41 may be connected to, for example, a ground layer incorporated in the printed wiring board 25.

The dummy pattern member 41 is formed rectangular and has a size slightly greater than the deformation suppressing member 29. The deformation suppressing member 29 is secured to the dummy pattern member 41 by solder 42. Thus, the deformation suppressing member 29 is secured to the dummy pattern member 41 by face. The deformation suppressing member 29 is secured to the dummy pattern member 41 not only by solder 42, but also by, for example, an adhesive, or a plurality of screws.

As shown in FIG. 4, the dummy pattern member 41 is provided on the second surface 32 away from the pads 35. Thus, the deformation suppressing member 29 secured to the dummy pattern member 41 is secured to the printed wiring board 25 away from the pads 35. Further, as shown in FIG. 3, the deformation suppressing member 29 is interposed between the corner 33a of the recess 33 of the printed wiring board 25 and the pads 35. Although the deformation suppressing member 29 is attached to the first surface 31 of the printed wiring board 25, it may be attached to the second surface 32.

As shown in FIG. 3, the deformation suppressing member 29 extends in the first direction D1. Accordingly, the deformation suppressing member 29 is substantially parallel to the row of the solder balls 37A. More specifically, the deformation suppressing member 29 has a side 29a adjacent to the row of the solder balls 37A. The side 29a extends substantially parallel to the extended line L1 of the row of the solder balls 37A. The positional relationship between the deformation suppressing member 29 and the solder balls 37A can be modified in various ways.

The deformation suppressing member 29 is adjacent to the row of the solder balls 37A in the second direction D2 perpendicular to the first direction D1. In other words, the side 29a of the deformation suppressing member 29 faces the row of the solder balls 37A.

The deformation suppressing member 29 extends in the first direction D1 such that the greater part of the member 29 exists away from the BGA 27, and projects in the first direction D1 relative to at least one end E1 (indicated by a one-dot chain line in FIG. 3) of the row of the solder balls 37A. In other words, the deformation suppressing member 29 extends in the first direction D1 over the one end E1.

The intermediate portion 29b of the deformation suppressing member 29 is provided at the position oriented by the angle defined between the row of the solder balls 37A in the first direction D1 and the column of the solder balls 37B in the second direction D2. In other words, the intermediate portion 29b of the deformation suppressing member 29 exist at the position at which the deformation suppressing member 29 intersects the line L2 (indicated by another one-dot chain line in FIG. 3) that divides, into two equal parts, the angle between the row of the solder balls 37A and the column of the solder ball 37B.

The deformation suppressing member 29 is positioned in one of the areas on the second surface 32 of the printed wiring board 25, which are defined by the extended line L1. Namely, in FIG. 3, the deformation suppressing member 29 is positioned above the row of the solder balls 37A and does not exist leftward, rightward or downward of the row of the solder balls 37A. Thus, the deformation suppressing member 29 does not surround the BGA 27, i.e., the periphery of the BGA 27 is not blocked.

When the television 1 has received a physical shock, the shock is transferred from the housing 10 to the printed wiring board 25 via the screws. Upon receiving the shock, a bending deformation will occur in the printed wiring board 25. Also when various components are mounted on the printed wiring board 25, a bending deformation may occur.

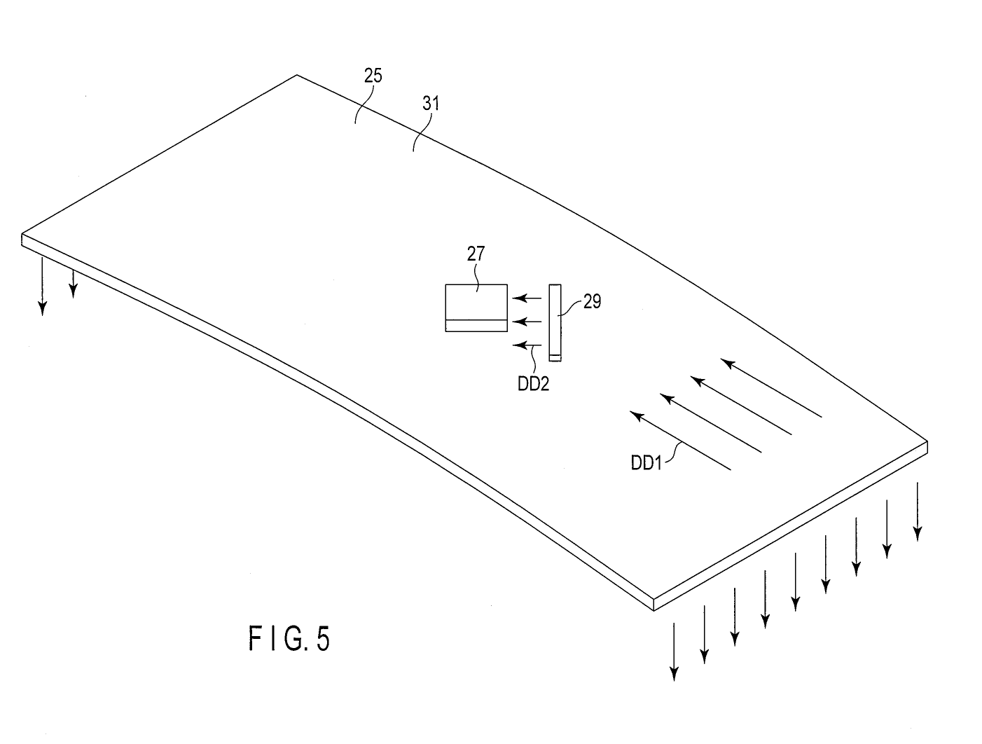

FIG. 5 is an exemplary schematic perspective view illustrating a case where a bending deformation has occurred in the printed wiring board 25. In FIG. 5, for facilitating the description, similar elements are denoted by reference numbers corresponding to those used in FIGS. 1 to 4. However, in FIG. 5, each element differs in shape or position from the corresponding element in FIGS. 1 to 4. More specifically, in FIG. 5, the printed wiring board 25 is formed of a rectangular plate, and the BGA 27 is located obliquely with respect to the length of the printed wiring board 25.

The term “bending deformation” used in this specification means a deformation in which the printed wiring board 25 is bent arcuate when a vertical force is exerted on the first surface 31 of the printed wiring board 25, as is shown in FIG. 5. In the example of FIG. 5, forces are exerted on the longitudinal opposite ends of the printed wiring board 25.

To facilitate explanation of the bending deformation of the printed wiring board 25, a first bending direction is indicated by arrows DD1 in FIG. 5. The first bending direction DD1 indicates a direction in which the printed wiring board 25 is curved when a bending deformation has occurred in the printed wiring board 25. Specifically, the first bending direction DD1 in FIG. 5 is directed from one end toward the other end along the length of the printed wiring board 25. When a bending deformation has occurred in the printed wiring board 25, the cross section of the printed wiring board 25 in the first bending direction DD1 is, for example, arcuate or wave-shaped. In contrast, the cross section of the printed wiring board 25 in the direction perpendicular to the first bending direction DD1 is linear since it is not influenced by the bending deformation.

With reference to FIG. 5, a description will be given of a case where the line of the first bending direction DD1 is at an angle of 45° relative to the square BGA 27 mounted on the printed wiring board 25. In FIG. 5, the line of one corner of the BGA 27 and the corresponding diagonal corner thereof coincides with the line of the first bending direction DD1.

Supposing that there is no deformation suppressing member 29 adjacent to the BGA 27, the stress resulting from the bending deformation of the printed wiring board 25 will concentrate on the connection between the one of the solder balls 37 arranged in a matrix, which is positioned at a corner of the BGA 27, and the corresponding pad 35. As a result, this connection may well be damaged.

On the other hand, in the first embodiment, when the printed wiring board 25 has received a physical shock, a bending deformation may occur, beginning at the corner 33a of the recess 33 of the printed wiring board 25. The direction in which the bending deformation beginning at the corner 33a grows may coincide with the first bending direction DD1 that is inclined by 45° with respect to the square BGA 27. Therefore, supposing that there is no deformation suppressing member 29 between the corner 33a and the BGA 27, stress may concentrate on the connection between the pad 35 and the one of the solder ball 37A or 37B positioned at the corresponding corner of the BGA 27.

In the first embodiment, the deformation suppressing member 29 secured to the printed wiring board 25 is interposed between the corner 33a of the recess 33 and the BGA 27. Accordingly, as shown in FIGS. 3 and 5, the bending deformation of the printed wiring board 25 in the first bending direction DD1 is converted into a bending deformation in a second bending direction DD2 perpendicular to the first direction D1 by the rigidity unique to the deformation suppressing member 29. In other words, the second bending direction DD2 is perpendicular to the length of the deformation suppressing member 29 and also to the row of the solder ball 37A.

When the bending deformation occurring in the printed wiring board 25 in the second bending direction DD2 reaches the area in which the BGA 27 is mounted, stress will occur on the respective connections of the solder balls 37A and the pads 35 arranged in the first direction D1. Thus, there is no possibility of stress concentrating on the connection between particular solder ball 37 and pad 35. Namely, the load resulting from the bending deformation of the printed wiring board 25 is substantially uniformly dispersed to the connections of the solder balls 37A and the corresponding pads 35.

It is sufficient if the deformation suppressing member 29 converts part of the bending deformation occurring in the printed wiring board 25 in the first bending direction DD1 into a bending deformation in the second bending direction DD2. That is, the stress, which results from the bending deformation of the printed wiring board 25 in the first bending direction DD1 or in the other direction, may occur in the connection between one of the solder balls 37 at one corner of the BGA 27 and the corresponding pad 35. Also in this case, part of the bending deformation of the printed wiring board 25 in the first bending direction DD1 is converted into the bending deformation of the same in the second bending direction DD2. As a result, the load exerted on the connection between the above-mentioned solder ball 37 and pad 35 is reduced.

In the television 1 of the first embodiment, the deformation suppressing member 29 is secured to the printed wiring board 25 with the BGA 27 mounted thereon. The deformation suppressing member 29 extends in the same first direction D1 as in which the solder balls 37A are arranged, such that the greater part of the deformation suppressing member 29 exists away from the BGA 27 and projects in the first direction D1 relative to the end E1 of the row of the solder balls 37A.

There may be a case where a bending deformation in a direction other than the second bending direction DD2 perpendicular to the first direction D1, for example, in the first bending direction DD1, occurs on the printed wiring board 25. In this case, in the first embodiment, direct influence of the bending deformation in the first bending direction DD1 upon the one solder ball 37A at the end of the row can be suppressed.

More specifically, since the greater part of the deformation suppressing member 29 exists away from the BGA 27 and projects in the first direction D1 relative to the end E1 of the row of the solder balls 37A, the bending deformation in the first bending direction DD1 reaches the deformation suppressing member 29 before reaching the solder ball 37A positioned at the end E1 of the row. At this time, since the deformation suppressing member 29 has a higher rigidity than the printed wiring board 25, the bending deformation reaching the deformation suppressing member 29 is converted into a bending deformation in the second bending direction DD2 perpendicular to the first direction D1 before reaching the solder ball 37A positioned at the end E1 of the row.

The bending deformation in the second bending direction DD2 reaches the connections of the solder balls 37A and the corresponding pads 35. This bending deformation advances in the second direction D2 perpendicular to the row of the solder balls 37A. Consequently, the bending deformation in the second bending direction DD2 is substantially uniformly exerted on the connections between the solder balls 37A and the corresponding pads 35. Thus, when a bending deformation has occurred in the printed wiring board 25, load is dispersed on the plurality of connections between the solder balls 37A and the pads 35.

As described above, in the first embodiment, concentration of stress in the connection between a particular solder ball 37 and the pad 35 corresponding thereto is suppressed. For instance, in the first embodiment, the stress occurring in the solder ball 37A or 37B, which is included in the solder balls 37 arranged in a matrix, and is positioned at a corner (i.e., the upper left corner in FIG. 3) of the square BGA 27, is reduced by approx. 10%, compared to the case where the deformation suppressing member 29 is not provided. Namely, the deformation suppressing member 29 converts the bending deformation occurring in the printed wiring board 25 so as to reduce the load on the connections between the solder balls 37 and the pads 35. As a result, the solder balls 37 of the BGA 27 can be surely connected to the pads 35 on the printed wiring board 25, thereby enhancing the reliability of the resultant device.

The deformation suppressing member 29 is secured to the printed wiring board 25 at a position away from the pads 35. Therefore, even when other components or wiring closely exist around the pads 35, it is not necessary to worry about the location of the deformation suppressing member 29, which enhances the degree of freedom in designing the module 13.

The deformation suppressing member 29 is interposed between the corner 33a of the recess 33 of the printed wiring board 25 and the pads 33. In other words, the deformation suppressing member 29 is interposed between the position that may be the origin of a bending deformation and the pads 35. By virtue of this structure, the deformation suppressing member 29 can reliably convert, to a desired direction, the direction of the bending deformation force exerted on the printed wiring board 25.

The deformation suppressing member 29 is provided at the position oriented by the angle defined between the row of the solder balls 37A in the first direction D1 and the column of the solder balls 37B in the second direction D2. This structure enables the deformation suppressing member 29 to suppress the bending deformation occurring in the printed wiring board 25 from directly affecting the connection between one solder ball 37 (37A or 37B) at the corner defined by the row of the solder balls 37A and the column of the solder balls 37B, and the pad 35 corresponding to the one solder ball.

Furthermore, in the first embodiment, the deformation suppressing member 29 exists in one of the areas, into which the printed wiring board 25 is divided by the line L1 extending along the row of the solder balls 37A. In other words, the deformation suppressing member 29 faces the row of the solder balls 37A on one side, and does not surround the BGA 27. Therefore, the deformation suppressing member 29 can be made compact. This compact deformation suppressing member 29 can prevent occurrence of significant stress in the connections between the solder balls 37 and the pads 35 due to the bending deformation of the printed wiring board 25.

By virtue of the above-described structure, the module 13 can be made relatively light although the deformation suppressing member 29 is secured to the printed wiring board 25. Further, since the space on the printed wiring board 25 required by the deformation suppressing member 29 can be reduced, the wiring patterns on the printed wiring board 25 can be designed rather freely in spite of the existence of the deformation suppressing member 29, thereby increasing the degree of freedom in designing the module 13.

### Second Embodiment

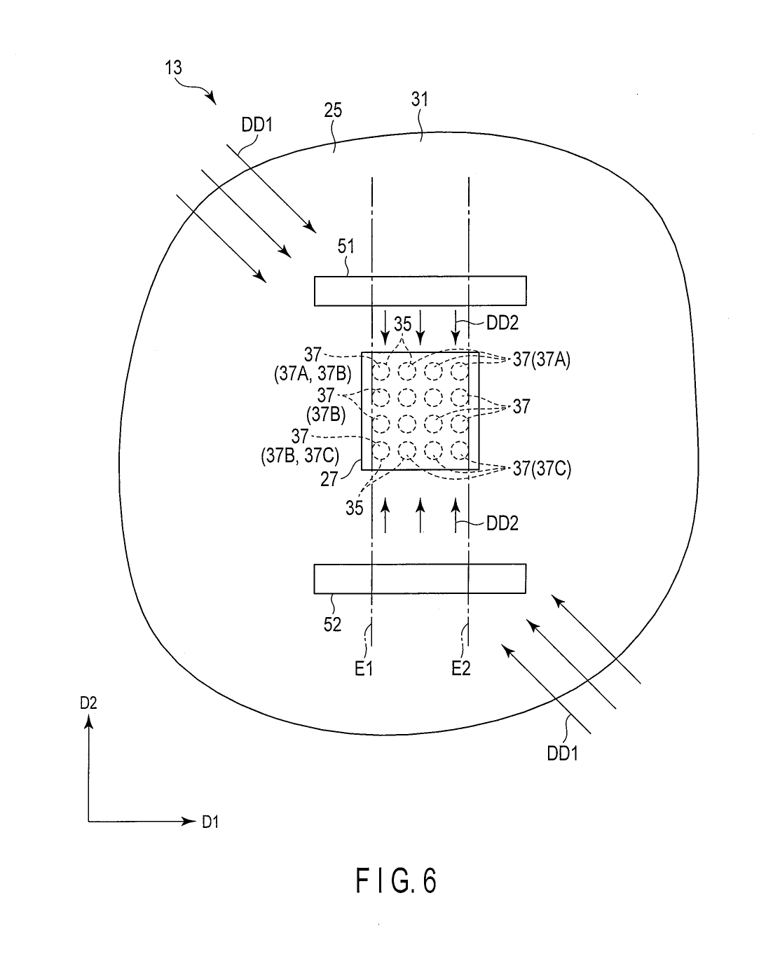

FIG. 6 shows a second embodiment. In the second embodiment, elements similar to those of the first embodiment are denoted by corresponding reference numbers, and part or all of the explanation of such an element is omitted.

FIG. 6 is an exemplary plan view illustrating part of a module 13 according to the second embodiment. As shown in FIG. 6, a first deformation suppressing member 51 and a second deformation suppressing member 52 are secured on the first surface 31 of the printed wiring board 25.

In the second embodiment, a plurality of solder balls 37 arranged in the first direction D1 on the opposite side of the solder balls 37A will be referred to as “the solder balls 37C” for convenience. The one of the solder balls 37 that is positioned at the lower left corner is regarded as a solder ball 37B and also as a solder ball 37C.

Both the first and second deformation suppressing members 51 and 52 are formed of a rectangular metal plate, like the deformation suppressing member 29 of the first embodiment and extend in the first direction D1. Namely, the first and second deformation suppressing members 51 and 52 are parallel to each other.

The first deformation suppressing member 51 is adjacent to the row of the solder balls 37A in the second direction D2. Similarly, the second deformation suppressing member 52 is adjacent to the row of the solder balls 37C in the second direction D2. The BGA 27 is interposed between the first and second deformation suppressing members 51 and 52. The distance between the BGA 27 and the first deformation suppressing member 51 may be equal to or different from the distance between the BGA 27 and the second deformation suppressing member 52.

In the first direction D1, the opposite ends of the first deformation suppressing member 51 project relative to the opposite ends E1 and E2 of the rows of the solder balls 37A and 37C indicated by the respective one-dot chain lines in FIG. 6. Similarly, the opposite ends of the second deformation suppressing member 52 project in the first direction D1 relative to the opposite ends E1 and E2 of the rows of the solder balls 37A and 37C indicated by the respective one-dot chain lines in FIG. 6. Consequently, the solder balls 37 arranged in a matrix exist within the area sandwiched by the first and second deformation suppressing members 51 and 52.

In the second embodiment, the solder balls 37 arranged in a matrix are completely within the area sandwiched by the first and second deformation suppressing members 51 and 52. Therefore, even if a bending deformation occurs in the printed wiring board 25 in any direction other than the first direction D1, it will be converted by the first and second deformation suppressing members 51 and 52 into a bending deformation in the second bending direction DD2.

The bending deformation of the printed wiring board 25 in the second bending direction DD2 causes substantially uniform stress to be generated in the connections between the solder balls 37A and the pads 35 arranged in the first direction D1, and in the connections between the solder balls 37C and the pads 35 arranged in the first direction D1. This can suppress concentration, on the connection between a particular solder ball 37 and the pad 35 corresponding thereto, of the stress resulting from the bending deformation of the printed wiring board 25. Consequently, the solder balls 37 of the BGA 27 can be surely connected to the pads 35 on the printed wiring board 25, thereby enhancing the reliability of the resultant device.

Further, although the first and second deformation suppressing members 51 and 52 sandwich the BGA 27, they do not surround the same. In other words, the BGA 27 is not blocked in the first direction D1 on the first surface 31 of the printed wiring board 25. This structure enables a plurality of wiring patterns extending from the pads 35 to be led freely on the first surface 31 of the printed wiring board 25, thereby increasing the degree of freedom in designing the module 13.

### Third Embodiment

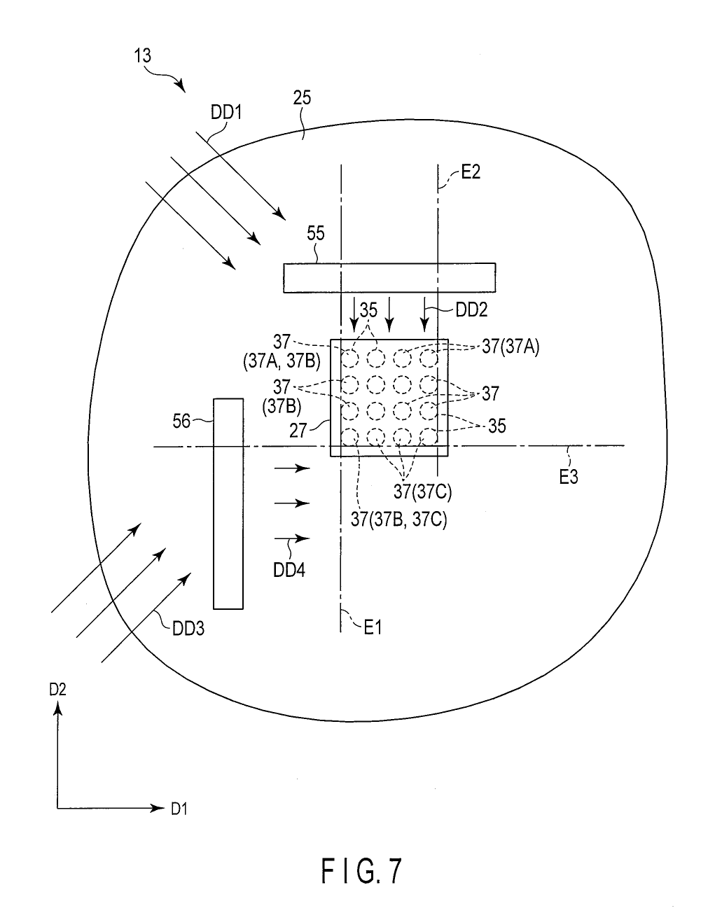

FIG. 7 shows a third embodiment. FIG. 7 is an exemplary plan view illustrating part of a module 13 according to the third embodiment. As shown in FIG. 7, a first deformation suppressing member 55 and a second deformation suppressing member 56 are secured on the first surface 31 of the printed wiring board 25.

Both the first and second deformation suppressing members 55 and 56 are formed of a rectangular metal plate, like the deformation suppressing member 29 of the first embodiment. The first deformation suppressing member 55 extends in the first direction D1, while the second deformation suppressing member 56 extends in the second direction D2. Thus, the first and second deformation suppressing members 55 and 56 are perpendicular to each other on the first surface 31 of the printed wiring board 25.

The first deformation suppressing member 55 is adjacent to the row of the solder balls 37A in the second direction D2. Further, in the first direction D1, the opposite ends of the first deformation suppressing member 55 project relative to the opposite ends E1 and E2 of the rows of the solder balls 37A and 37C indicated by the respective one-dot chain lines in FIG. 7.

In contrast, the second deformation suppressing member 56 is adjacent to the column of the solder balls 37B in the first direction D1. Further, the second deformation suppressing member 56 projects in the second direction D2 relative to the one end E3 of the column of the solder balls 37B indicated by the other one-dot chain line in FIG. 7.

In the third embodiment, the second deformation suppressing member 56 projects in the second direction D2 relative to the one end E3 of the column of the solder balls 37B. In the third embodiment, there may be a case where a bending deformation may occur in the printed wiring board 25 in, for example, the first bending direction DD1 or in a third bending direction DD3 perpendicular to the first bending direction DD1.

In this case, the second deformation suppressing member 56 converts the bending deformation of the printed wiring board 25 in the third bending direction DD3 into a bending deformation in the fourth bending direction DD4 perpendicular to the second direction D2. In other words, the fourth bending direction DD4 is perpendicular to the length of the second deformation suppressing member 56 and to the column of the solder balls 37B.

The bending deformation of the printed wiring board 25 in the fourth bending direction DD4 causes substantially uniform stress in the connections between the solder balls 37B and pads 35 arranged in the second direction D2. Thus, concentration of stress on the connection between a particular solder ball 37 and the pad 35 corresponding thereto, which is caused by the bending deformation of the printed wiring board 25, can be suppressed. As a result, the solder balls 37 of the BGA 27 can be reliably connected to the pads 35 on the printed wiring board 25, thereby enhancing the reliability of the resultant device.

Furthermore, the first deformation suppressing member 55 suppresses the bending deformation of the printed wiring board 25 in the fourth bending direction DD4. Similarly, the second deformation suppressing member 56 suppresses the bending deformation of the printed wiring board 25 in the second bending direction DD2. This structure suppresses the bending deformation of the printed wiring board 25 near the pads 35 to thereby prevent stress from occurring in the connections between the pads 35 and the solder balls 37.

### Fourth Embodiment

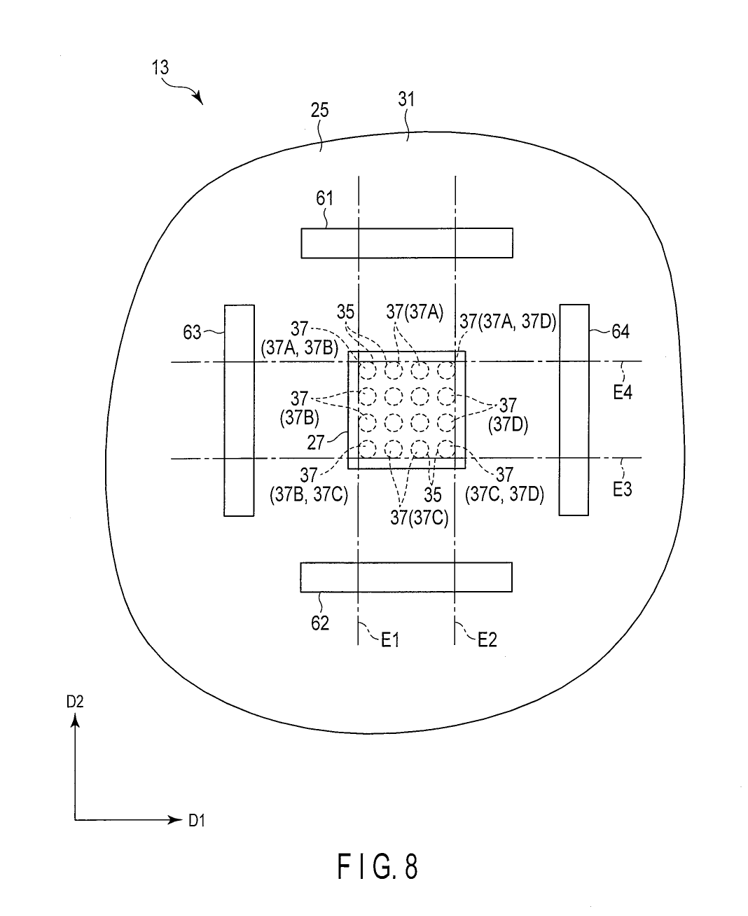

FIG. 8 shows a fourth embodiment. FIG. 8 is an exemplary plan view illustrating part of a module 13 according to the fourth embodiment. As shown in FIG. 8, a first deformation suppressing member 61, a second deformation suppressing member 62, a third deformation suppressing member 63 and a fourth deformation suppressing member 64 are secured on the first surface 31 of the printed wiring board 25. The first to fourth deformation suppressing member 61 to 64 are separate from each other.

In the fourth embodiment, a plurality of solder balls 37 arranged in the second direction D2 on the opposite side of the solder balls 37B will be referred to as “the solder balls 37D” for convenience. The one of the solder balls 37 that is positioned at the lower right corner is regarded as a solder ball 37C and also as a solder ball 37D.

The first to fourth deformation suppressing members 61 to 64 are formed of a rectangular metal plate, like the deformation suppressing member 29 of the first embodiment. The first and second deformation suppressing members 61 and 62 extend in the first direction D1. The third and fourth deformation suppressing members 63 and 64 extend in the second direction D2.

The first deformation suppressing member 61 is adjacent to the row of the solder balls 37A in the second direction D2. Similarly, the second deformation suppressing member 62 is adjacent to the row of the solder balls 37C in the second direction D2. The third deformation suppressing member 63 is adjacent to the column of the solder balls 37B in the first direction D1. Similarly, the fourth deformation suppressing member 64 is adjacent to the column of the solder balls 37D in the first direction D1. The BGA 27 is surrounded by the first to fourth deformation suppressing members 61 to 64 on the first surface 31 of the printed wiring board 25.

The opposite ends of the first deformation suppressing member 61 project in the first direction D1 relative to the opposite ends E1 and E2 of the row of the solder balls 37A indicated by one-dot chain lines in FIG. 8. Similarly, the opposite ends of the second deformation suppressing member 62 project in the first direction D1 relative to the opposite ends E1 and E2 of the row of the solder balls 37C indicated by the one-dot chain lines in FIG. 8. The opposite ends of the third deformation suppressing member 63 project in the second direction D2 relative to the opposite ends E3 and E4 of the column of the solder balls 37B indicated by the other one-dot chain lines in FIG. 8. Similarly, the opposite ends of the fourth deformation suppressing member 64 project in the second direction D2 relative to the opposite ends E3 and E4 of the column of the solder balls 37D indicated by the other one-dot chain lines in FIG. 8. Thus, the solder balls 37 arranged in a matrix are surrounded by the first to fourth deformation suppressing members 61 to 64 on the first surface 31 of the printed wiring board 25.

In the fourth embodiment, the solder balls 37 arranged in a matrix completely fall within the area surrounded by the first to fourth deformation suppressing members 61 to 64. Accordingly, when a bending deformation in any direction occurs in the printed wiring board 25, it is always converted into a bending deformation in the second bending direction DD2 and that in the fourth bending direction DD4 shown in FIG. 7. The bending deformation of the printed wiring board 25 in the second and fourth bending directions DD2 and DD4 causes substantially the same stress in the connections between the solder balls 37A, 37B, 37C and 37D and the pads 35 corresponding thereto. Therefore, concentration of stress on the connection between a particular solder ball 37 and the pad 35 corresponding thereto due to the bending deformation of the printed wiring board 25 can be suppressed. This enables the solder balls 37 of the BGA 27 to be securely connected to the pads 35 of the printed wiring board 25, thereby enhancing the reliability of the resultant device.

The first and second deformation suppressing members 61 and 62 suppress the bending deformation of the printed wiring board 25 in the fourth bending direction DD4. Similarly, the third and fourth deformation suppressing members 63 and 64 suppress the bending deformation of the printed wiring board 25 in the second bending direction DD2. As a result, the bending deformation of the printed wiring board 25 near the pads 35 is suppressed, thereby preventing stress from occurring in the connections between the pads 35 and the solder balls 37.

In addition, since the first to fourth deformation suppressing members 61 to 64 are separate from each other on the first surface 31 of the printed wiring board 25, wiring patterns extending from the pads 35 can be passed between adjacent ones of the first to fourth deformation suppressing members 61 to 64. This enhances the degree of freedom in designing the module 13.

Further, in the fourth embodiment, the first to fourth deformation suppressing members 61 to 64 may be coupled to each other. In this structure, the entire periphery of the BGA 27 can be surrounded by the first to fourth deformation suppressing members 61 to 64, whereby the bending deformation of the printed wiring board 25 around the pads 35 can be reliably suppressed.

### Fifth Embodiment

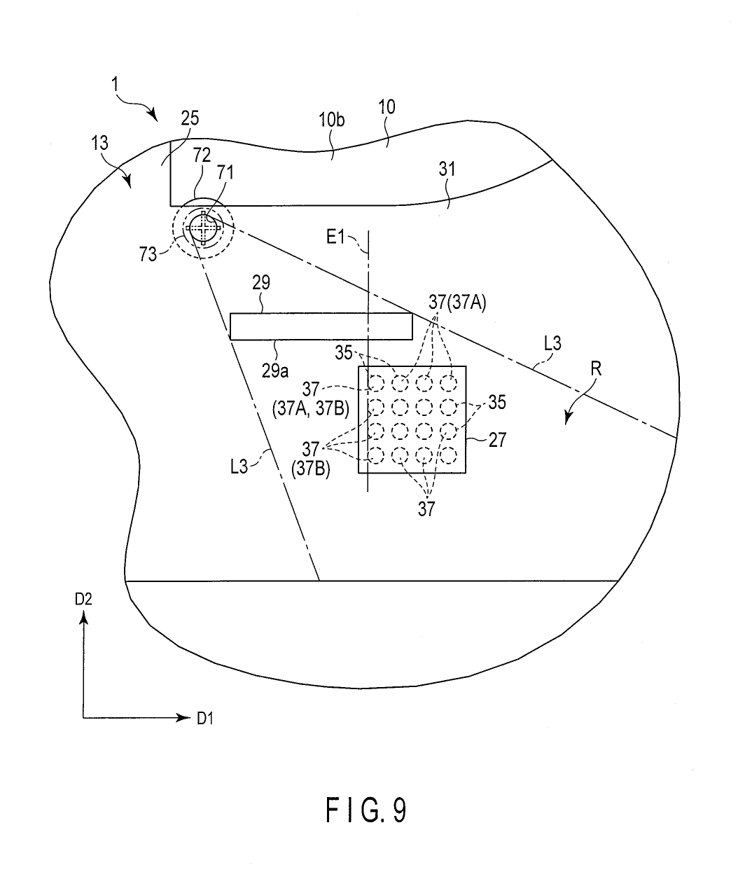

FIG. 9 shows a fifth embodiment. FIG. 9 is an exemplary plan view illustrating the interior of a television 1 according to the fifth embodiment. As shown in FIG. 9, a hole 71 is formed in the printed wiring board 25. Further, a boss 72 is provided on an inner surface 10b of the housing 10. A screw 73, which is indicated by the two-dot line in FIG. 9, is screwed into the screw hole of the boss 72 through the hole 71. The screw 73 is an example of a fixing member. The printed wiring board 25 is secured to the housing 10 by the screw 73. Namely, the printed wiring board 25 is fixed to the housing 10 at the position of the hole 71. Therefore, the hole 71 is regarded as an example of means fixed to the housing 10 by the fixing member.

As shown in FIG. 9, the deformation suppressing member 29 secured to the first surface 31 of the printed wiring board 25 is interposed between the hole 72 and the row of the solder balls 37A. Namely, the deformation suppressing member 29 is provided between the pads 35 and the position at which the printed wiring board 25 is fixed to the housing 10. More specifically, the deformation suppressing member 29 is provided between the position at which the bending deformation of the printed wiring board 25 starts, and the pads 35.

By securing the deformation suppressing member 29 to the printed wiring board 25, a deformation suppressing region R is formed on the first surface 31 of the printed wiring board 25. The deformation suppressing region R is defined on the first surface 31, using two imaginary lines L3 that are formed by connecting the hole 71 to the longitudinal opposite ends of the deformation suppressing member 29.

When the television 1 receives a physical shock, the shock is transferred from the housing 10 to the printed wiring board 25 via the screw 73. Thus, a bending deformation starting at the hole 71 occurs in the printed wiring board 25. In the deformation suppressing region R, the bending deformation of the printed wiring board 25 is converted by the deformation suppressing member 29 into a bending deformation in the second bending direction DD2.

The pads 35 of the printed wiring board 25 are located in the deformation suppressing region R. Accordingly, a bending deformation in the second bending direction DD2 is exerted on the connections between the pads 35 and the solder balls 37 connected thereto. Thus, concentration, on the connection between a particular solder ball 37 and the pad 35 corresponding thereto, of the stress resulting from the bending deformation of the printed wiring board 25 is suppressed. Consequently, the solder balls 37 of the BGA 27 can be surely connected to the pads 35 of the printed wiring board 25 to thereby enhance the reliability of the resultant device.

The component mounted on the printed wiring board is not limited to the BGA, but may be an area-array type electronic component, a peripheral type electronic component, or another component with a plurality of terminals arranged in a row or rows.

Further, the component is not limited to a surface mount device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus comprising:
a substrate comprising a plurality of conductors;
a component comprising a plurality of first terminals in a first direction, the first terminals being connected to the conductors; and
a deformation suppressing member attached to the substrate, and configured to convert a certain bending deformation into a bending deformation in a direction perpendicular with the first direction when the certain bending deformation occurs in the substrate.

2. The electronic apparatus of claim 1, wherein the deformation suppressing member extends in the first direction on the substrate, and is adjacent to a line of the first terminals in the direction perpendicular to the first direction.

3. The electronic apparatus of claim 2, wherein the deformation suppressing member projects in the first direction relative to at least one end of the line of the first terminal.

4. The electronic apparatus of claim 2, wherein the deformation suppressing member is more rigid than the substrate.

5. The electronic apparatus of claim 4, wherein the deformation suppressing member is thinner than the substrate.

6. The electronic apparatus of claim 2, wherein
the component further comprises a plurality of second terminals connected to the conductors and arranged in a second direction perpendicular to the first direction; and
a portion of the deformation suppressing member is situated at a position oriented by an angle between the line of the first terminals in the first direction and a line of the second terminals in the second direction.

7. The electronic apparatus of claim 6, wherein the conductors are arranged in a matrix on the substrate.

8. The electronic apparatus of claim 7, wherein the first and second terminals are arranged in a matrix in accordance with the conductors.

9. The electronic apparatus of claim 2, wherein the substrate comprises a first surface with the conductors mounted thereon, and a second surface opposite to the first surface, the deformation suppressing member being secured to the second surface.

10. The electronic apparatus of claim 2, wherein the substrate comprises a first surface with the conductors mounted thereon, and a second surface opposite to the first surface, the deformation suppressing member being secured to the first surface.

11. The electronic apparatus of claim 2, wherein the deformation suppressing member is situated in one of regions into which the substrate is divided by a line extending along the line of the first terminals.

12. The electronic apparatus of claim 2, further comprising a housing configured to contain the substrate, and a fixing member configured to fix the substrate to the housing, wherein the deformation suppressing member is interposed between a portion of the substrate fixed to the housing by the fixing member, and the line of the first terminals.

13. The electronic apparatus of claim 12, wherein the conductors are located within a region defined by imaginary lines that connect the portion of the substrate fixed to the housing by the fixing member, to opposite ends of the deformation suppressing member.

14. An electronic apparatus comprising:
a substrate comprising a plurality of conductors;
a component comprising a plurality of terminals connected to the conductors, the terminals being arranged in a first direction and a second direction perpendicular to the first direction; and
a plurality of deformation suppressing members attached to the substrate to surround the component, the deformation suppressing members being configured to convert a certain bending deformation into a bending deformation in a direction perpendicular with the first direction and into a bending deformation in a direction perpendicular with the second direction when the certain bending deformation occurs in the substrate.

15. The electronic apparatus of claim 14, wherein one of the deformation suppressing members extends along a line of the terminals arranged in the first direction, and projects in the first direction relative to at least one end of the line of the terminals

16. The electronic apparatus of claim 15, wherein another of the deformation suppressing members extends along a line of the terminals arranged in the second direction, and projects in the second direction relative to at least one end of the line of the terminals.

17. An electronic apparatus comprising:
a substrate comprising a plurality of conductors;
a component comprising a plurality of terminals connected to the conductors, the terminals being arranged in a first direction and a second direction perpendicular to the first direction; and
a plurality of deformation suppressing members attached to the substrate, opposing each other with the component interposed therebetween, the deformation suppressing members being configured to convert a certain bending deformation into a bending deformation in a direction perpendicular with the first direction and into a bending deformation in a direction perpendicular with the second direction when the certain bending deformation occurs in the substrate.
